(19) United States
(12) Patent Application Publication
(10) Pub. No.: US 2012/0198693 A1
(43) Pub. Date: Aug. 9, 2012

(54) METHOD OF MANUFACTURING MULTI-BAND FRONT END MODULE

(75) Inventors: Kyung-O KIM, Anyang-si (KR); Tae-Eui Kim, Seoul (KR)

(73) Assignee: SAMSUNG ELECTRO-MECHANICS CO., LTD., Suwon (KR)

(21) Appl. No.: 13/448,692

(22) Filed: Apr. 17, 2012

Related U.S. Application Data
(62) Division of application No. 12/213,702, filed on Jun. 23, 2008.

(30) Foreign Application Priority Data
Dec. 21, 2007 (KR) 10-2007-0134941

(51) Int. Cl. H05K 3/10

(52) U.S. Cl. 29/846

(57) ABSTRACT

A method of manufacturing a multi-band front end module having an embedded passive element, the method including: preparing metal plates formed on either surface of an adhesion layer interposed therebetween; forming first circuit patterns on the plates; separating the plates by removing the adhesion layer; pressing one of the plates to one surface of an insulation layer and another of the plates to the other surface of the insulation layer; removing the plates to form the insulation layer having the first circuit patterns formed on either surface thereof; stacking dielectric layers on either surface of the insulation layer; and forming a second circuit pattern on the dielectric layers stacked on the either surface of the insulation layer.

### CROSS-REFERENCE TO RELATED APPLICATIONS

This application is a U.S. divisional application filed under 37 CFR 1.53(b) claiming priority benefit of U.S. Ser. No. 12/213,702 filed in the United States on Jun. 23, 2008, which claims earlier priority benefit to Korean Patent Application No. 10-2007-0134941 filed with the Korean Intellectual Property Office on Dec. 21, 2007 the disclosures of which are incorporated herein by reference.

### BACKGROUND

1. Field

The present invention relates to a multi-band front end module and a method of manufacturing the front end module.

2. Description of the Related Art

The trend in current electronic products is towards greater functionality, smaller size, and lower cost. In particular, mobile electronic products may require numerous active and passive elements that have to be mounted on the surfaces of a circuit board, and as such, there is a greater demand for methods of overcoming these limitations in size and thickness.

In accordance with the demands for smaller size and multi-functionality in mobile electronic products, much effort is being invested in developing the multi-band front end module (FEM). The multi-band FEM is a module that connects the antenna inside a cell phone with an RF chip to separate outgoing and incoming signals and perform filtering and amplifying operations. The multi-band FEM can thus be regarded as a product that includes a filter, a low-noise amplifier, and a power amplifier, etc., integrated into a single package.

One of the reasons for the active research performed for developing the multi-band FEM is that, because of the increasing complexity in the functions provided by an electronic device, the frequency employed by the electronic device is also increasing beyond a single band to multiple bands, while the device is expected to maintain a small size and a low cost.

As the front end module is made to support multiple bands, the number of parts included in the front end module may increase. However, it may also be required that the size of the front end module be reduced. In order to satisfy the demands in cost, size, and performance, manufacturers are working on new developments that involve the use of low temperature co-fired ceramic (LTCC) and organic substrates.

The use of LTCC may be advantageous in decreasing the size and obtaining the desired properties, while the use of organic substrates may provide more benefits in terms of reliability and yield. The multi-band front end module as developed in the related art mostly utilizes LTCC. Thus, there is a need for a multi-band front end module in which passive elements, such capacitors and inductors, are embedded in an organic substrate to implement passive components, such as filters, etc.

### SUMMARY

An aspect of the invention provides a method of manufacturing a multi-band front end module that includes embedding a passive element in an organic substrate, and a multi-band front end module formed by embedding a passive element in an organic substrate.

Another aspect of the invention provides a method of manufacturing a multi-band front end module having an embedded passive element. The method may include forming a first circuit pattern on one side of an insulation layer, stacking a dielectric layer over the one side of the insulation layer, and forming a second circuit pattern on the dielectric layer in correspondence with the first circuit pattern such that at least one of a capacitor and an inductor is implemented.

Here, the process for forming the first circuit pattern on the insulation layer can include forming the first circuit pattern on one side of a carrier, pressing the carrier onto the insulation layer with the one side of the carrier facing the insulation layer, and removing the carrier. The forming of the first circuit on the carrier can be performed by selectively depositing a plating layer over the carrier.

The carrier can include a pair of metal plates formed with an adhesion layer placed in-between. The operation of forming the second circuit pattern can be performed such that one or more capacitors and one or more inductors are formed, in order that a filter may be implemented.

Also, the method of manufacturing a multi-band front end module having an embedded passive element can further include forming a build-up board portion over a surface of the second circuit pattern and mounting an active element on a surface of the build-up board portion. The dielectric layer may further include a ceramic filler, where the ceramic filler can include barium titanate (BaTiO₃) or strontium titanate (SrTiO₃) or a combination of the two compounds. The insulation layer can be an organic insulation layer.

Yet another aspect of the invention provides a multi-band front end module having an embedded passive element. The multi-band front end module can include an insulation layer, a first circuit pattern formed on one side of the insulation layer, a dielectric layer stacked over the one side of the insulation layer, and a second circuit pattern formed on a surface of the dielectric layer. The second circuit pattern can be formed in correspondence with the first circuit pattern such that at least one of a capacitor and an inductor is implemented.

In certain embodiments, the front end module may further include a build-up board portion stacked over a surface of the second circuit pattern, and an active element mounted on a surface of the build-up board portion, where the active element can be connected with the build-up board portion by wire bonding.

Also, the dielectric layer can further include a ceramic filler, in which case the ceramic filler can include barium titanate (BaTiO₃) or strontium titanate (SrTiO₃) or a combination of the two compounds. The insulation layer can be made as an organic insulation layer.

The first circuit pattern may be buried in the insulation layer, and the second circuit pattern may be formed such that one or more capacitors and one or more inductors are formed, whereby a filter may be implemented.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a perspective view of a multi-band front end module having embedded passive elements according to an embodiment of the invention.

FIG. 2 is a perspective view of a multi-band front end module having embedded passive elements according to another embodiment of the invention.

FIG. 3, FIG. 4, FIG. 5, FIG. 6, FIG. 7, FIG. 8, FIG. 9, FIG. 10, FIG. 11, FIG. 12, FIG. 13, FIG. 14, and FIG. 15 are cross sectional views each representing a process in a method of manufacturing a multi-band front end module having an embedded passive element according to an embodiment of the invention.

FIG. 16 is a flowchart illustrating a method of manufacturing a multi-band front end module having an embedded passive element according to an embodiment of the invention.

### DESCRIPTION OF EMBODIMENTS

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various elements, such elements must not be limited to the above terms. The above terms are used only to distinguish one element from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Certain embodiments of the invention will be described below in more detail with reference to the accompanying drawings.

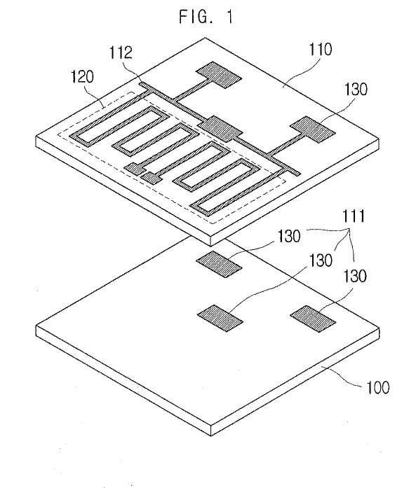

First, a description will be provided, with reference to FIG. 1, on the composition of a multi-band front end module having embedded passive elements according to an embodiment of the invention. FIG. 1 is a perspective view of a multi-band front end module having embedded passive elements according to an embodiment of the invention.

In FIG. 1, there are illustrated an insulation layer 100, a dielectric layer 110, a first circuit pattern 111, a second circuit pattern 112, capacitors 130, and inductors 120.

According to this embodiment, a first circuit pattern 111 can be formed buried in an insulation layer 100, and a second circuit pattern 112 can be formed on a surface of a dielectric layer 110. The insulation layer 100 can be an organic insulation layer, which refers to an insulation layer made of an organic substance. The first circuit pattern 111 and second circuit pattern 112 can form a filter.

Here, the second circuit pattern 112 can be formed in a position corresponding with the first circuit pattern 111. A position corresponding with the first circuit pattern 111 refers to a position at which the second circuit pattern 112 and first circuit pattern 111 can form one or more capacitor and/or one or more inductor.

If a portion of the second circuit pattern 112 is formed opposite a portion of the first circuit pattern 111, these portions of the circuit patterns 111, 112 and the interposed dielectric layer 110 can form capacitors 130. If a portion of the second circuit pattern 112 is formed in a position unrelated with the first circuit pattern 111, the portion of the second circuit pattern 112 can be used to form an inductor 120. In this way, the second circuit pattern 112 can be formed in a corresponding relationship with the first circuit pattern 111, to implement capacitors 130 and/or inductors 120. Moreover, the capacitors 130 and inductors 120 can implement resonators and couplers to form a filter.

For implementing the capacitor 130, a portion of the first circuit pattern 111 formed in the insulation layer 100 can form a lower electrode, while a portion of the second circuit pattern 112 formed on the dielectric layer 110 opposite the lower electrode can form an upper electrode, as in the example illustrated in FIG. 1. Also, the inductor 120 can be implemented by portions of the second circuit pattern 112 formed in positions unrelated to the first circuit pattern 111, as in the example illustrated in FIG. 1. Here, the inductor 120 can be formed in a generally zigzagging shape considering size limitation.

The capacitors 130 and inductors 120 formed in a manner described above can be used to form resonators and couplers, which may in turn be used to implement a filter. Here, serial capacitors can be used to adjust bandwidth, while notch filters, etc., can be used to improve attenuation characteristics, etc.

The dielectric layer 110, on which the second circuit pattern 112 may be formed, can further include a ceramic filler having high permittivity and low dielectric loss. According to this particular embodiment, the ceramic filler can include one of barium titanate (BaTiO₃) and strontium titanate (SrTiO₃), or a combination of the two compounds. A high permittivity value and a low dielectric loss value may be, for example, a permittivity of 20 or higher, and a dielectric loss of 0.01 or lower.

Thus, using passive elements such as capacitors, inductors, etc., embedded in an organic substrate such as the dielectric layer 110 and insulation layer 100, a more compact multi-band front end module can be provided. Multiple layers of insulation and circuit patterns can be formed over the surface of the second circuit pattern 112, where these layers will be referred to collectively as a build-up board portion.

Active elements can be mounted on the surface of the build-up board portion, and the active elements may be connected with the build-up board portion using surface-mounting techniques such as wire bonding. Here, the active elements may include at least one of a low-noise amplifier and a power amplifier.

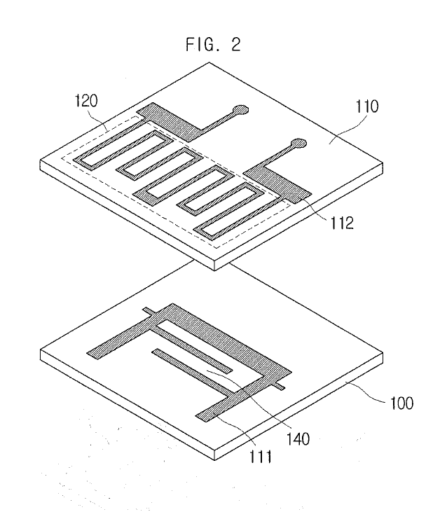

A description will now be provided, with reference to FIG. 2, on the composition of a multi-band front end module having embedded passive elements according to another embodiment of the invention. FIG. 2 is a perspective view of a multi-band front end module having embedded passive elements according to another embodiment of the invention.

In FIG. 2, there are illustrated an insulation layer 100, a dielectric layer 110, a first circuit pattern 111, a second circuit pattern 112, inductors 120, and a coupler 140. The basic composition of a multi-band front end module having embedded passive elements based on this embodiment is substantially the same as that of the embodiment described with reference to FIG. 1. As such, similar descriptions will not be repeated.

In the multi-band front end module having embedded passive elements according to this embodiment, an example of which is illustrated in FIG. 2, the second circuit pattern 112 formed on the dielectric layer 110 can be used to implement inductors 120. As in the example shown in FIG. 2, the first circuit pattern 111 and the second circuit pattern 112 can implement a resonator and form a coupler 140, to implement the desired properties of a filter. Thus, according to this embodiment, a resonator can be formed as a strip structure, and may use a transmission line of length λ/4, which can be more advantageous in terms of size reduction and which is relatively less affected by tolerances.

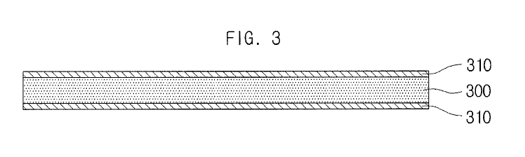

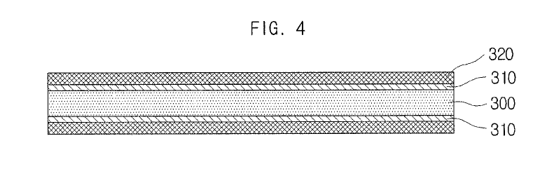

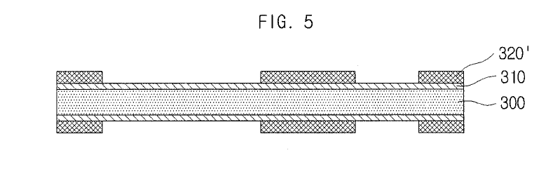

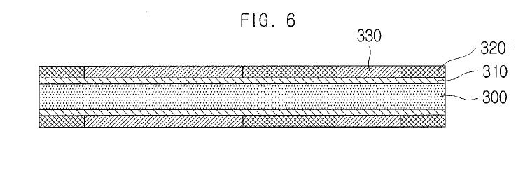

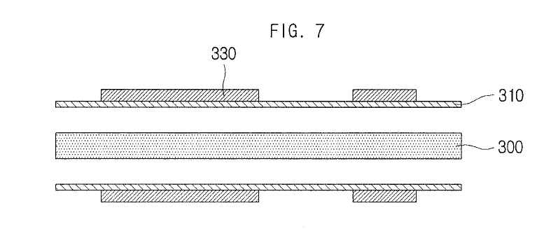

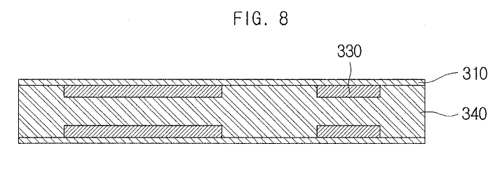

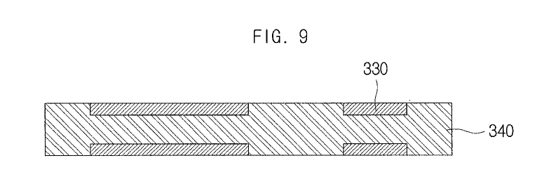

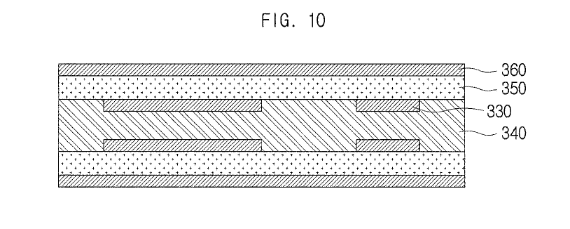

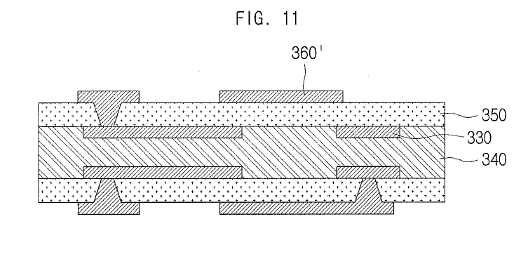

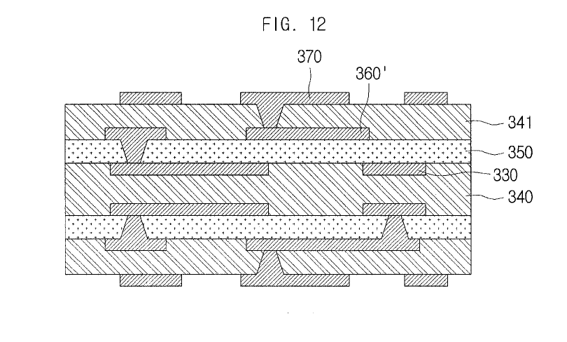

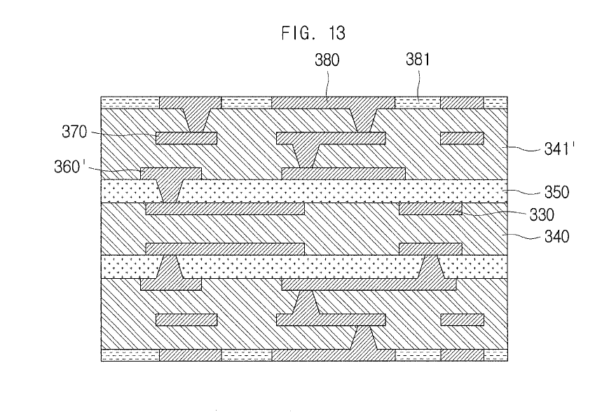

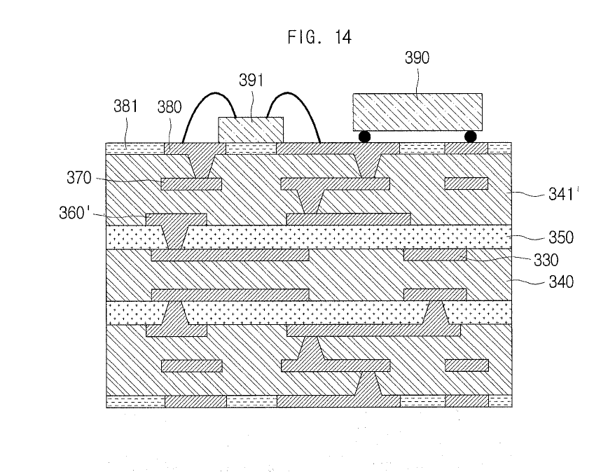

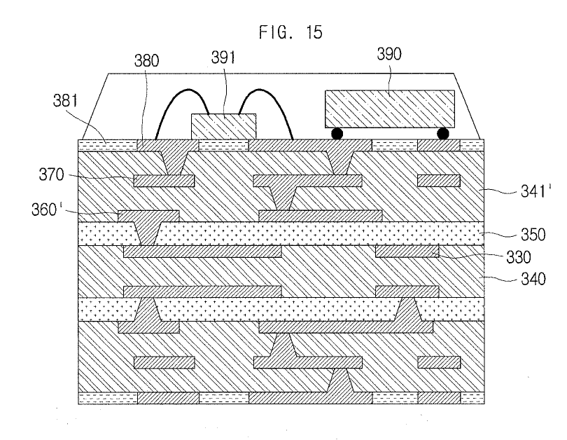

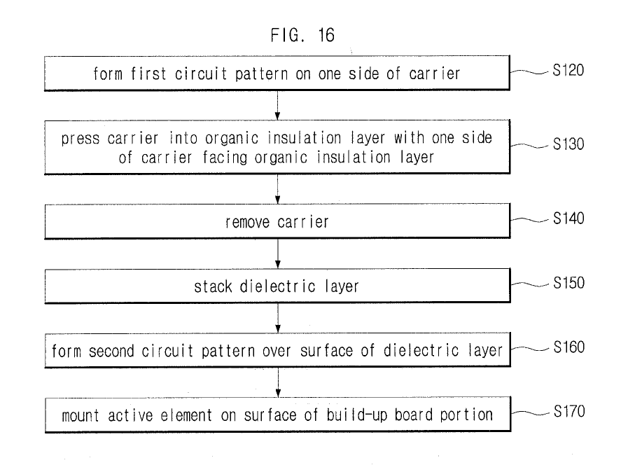

A description will now be provided, with reference to FIGS. 3 to 16, on a method of manufacturing a multi-band front end module having an embedded passive element according to an embodiment of the invention. FIG. 3 through FIG. 15 are cross sectional views each representing a process in a method of manufacturing a multi-band front end module having an embedded passive element according to an embodiment of the invention, and FIG. 16 is a flowchart illustrating a method of manufacturing a multi-band front end module having an embedded passive element according to an embodiment of the invention.

The descriptions will be provided for the example in which a pair of metal plates having an interposed adhesion layer is used as a carrier. Also, for convenience and better understanding, explanations on the composition of the multi-band front end module that are redundant in face of the descriptions provided above will not be repeated.

In FIGS. 3 to 15, there are illustrated a pair of metal plates 310, an adhesion layer 300, photoresists 320, 320′, first circuit patterns 330, organic insulation layers 340, 341, 341′, dielectric layers 350, plating layers 360, second circuit patterns 360′, third circuit patterns 370, fourth circuit patterns 380, solder resists 381, and active elements 390, 391.

According to this embodiment, a first circuit pattern 330 can first be formed in each side of an organic insulation layer 340. Here, the forming of the first circuit patterns 330 can be divided mainly into three operations.

As illustrated in FIG. 3, a pair of metal plates 310 can be provided that have an adhesion layer 300 formed in-between. The pair of metal plates 310 may later be removed by an etching process, and thus may be made of copper (Cu) or aluminum (Al). Next, the first circuit patterns 330 can be formed, one on each side of the pair of metal plates 310 (S120). In order to form the first circuit patterns, a photoresist 320, 320′ can be formed on either side of the pair of metal plates 310, and the portions that are to form the first circuit patterns can be developed for removal. Then, as illustrated in FIG. 6, the first circuit patterns 330 can be formed in place of the removed portions of the photoresists 320′. Forming the first circuit patterns 330 by selectively depositing plating layers, as described above, can produce fewer errors in the circuits compared to the conventional tenting method.

Next, as illustrated in FIG. 7, the photoresists 320′ can be removed, and the pair of metal plates 310 can be detached by heating the pair of metal plates 310 and the interposed adhesion layer 300. The adhesion layer 300 can be a foam-producing adhesion layer.

Next, as illustrated in FIG. 8, the pair of metal plates 310 can be pressed into an organic insulation layer 340, with the side of each of the pair of metal plates 310 on which the first circuit pattern 330 facing the organic insulation layer 340 (S130). The organic insulation layer 340 can be made of a typical epoxy material, and a material can be selected that does not leave gaps when the first circuit patterns are buried.

Afterwards, as illustrated in FIG. 9, the pair of metal plates 310 can be removed (S140). Here, the pair of metal plates 310 can be removed by an etchant. Onto each surface of the organic insulation layer 340, from which the metal plate 310 is removed, a dielectric layer 350 can be stacked on (S150). As described above, the dielectric layers 350 may further include a ceramic filler having high permittivity and low dielectric loss.

Then, a plating layer 360 on each of the surfaces of the dielectric layers 350 can be etched to form a second circuit pattern 360′ (S160). As described above, the second circuit patterns 360′ can be formed to correspond with the first circuit patterns 330, so as to form inductors and capacitors, where multiple inductors and capacitors can be used to form a filter.

Next, as illustrated in FIGS. 12 and 13, additional organic insulation layers 341, 341′, third circuit patterns 370, and fourth circuit patterns 380 can be formed to obtain multiple layers of organic substrates. The organic insulation layers 341, 341′, third circuit pattern 370, and fourth circuit pattern 380 formed over the second circuit pattern may be referred to collectively as a build-up board portion. Subsequent uses of the term build-up board portion will entail the same meaning. The number of layers included in the build-up board portion may vary according to the number of components embedded and the overall size of the module, so that a multi-layer board of six layers or more can be manufactured.

In order to interconnect circuit patterns on different layers, via processing and/or plating processes may be performed. Also, a ground layer may be formed, in order to remove noise and provide stable performance in the embedded passive components.

Then, as illustrated in FIG. 14, active elements 390, 391 can be mounted on the surface of the build-up board portion (S170). The active elements 390, 391 may be connected with the build-up board portion using surface-mounting techniques such as wire bonding. The active elements can include at least one of a low-noise amplifier and a power amplifier or a combination of the two. Also, as illustrated in FIG. 15, a molding can be provided to protect the active elements, so that these may be utilized as an integrated part.

As set forth above, certain embodiments of the invention provide a multi-band front end module and a method of manufacturing the front end module, which allows the positioning of various passive elements while maintaining a compact size for the multi-band front end module.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention. As such, many embodiments other than those set forth above can be found in the appended claims.

What is claimed is:

1. A method of manufacturing a multi-band front end module having an embedded passive element, the method comprising:
preparing a pair of metal plates formed on either surface of an adhesion layer interposed therebetween;
forming a first circuit pattern on a surface of each of the pair of metal plates;
separating the pair of metal plates by removing the adhesion layer;
pressing one of the pair of metal plates to one surface of an insulation layer and the other of the pair of metal plates to the other surface of the insulation layer in such a way that the first circuit patterns are buried in the insulation layer;
removing the pair of metal plates to form the insulation layer having the first circuit patterns formed on either surface thereof;
stacking dielectric layers on the either surface of the insulation layer; and
forming a second circuit pattern on the dielectric layers stacked on the either surface of the insulation layer,
wherein one portion of the second circuit pattern is formed at a location that is opposite to the first circuit pattern with the dielectric layer therebetween in such a way that a predesigned form of capacitor is realized, and the other portion of the second circuit pattern is formed at a location that is not opposite to the first circuit pattern in such a way that a predesigned form of inductor is realized.

2. The method of claim 1, wherein the forming the first circuit pattern is performed by selectively depositing a plating layer over the pair of metal plates.

3. The method of claim 1, wherein the pair of metal plates formed with an adhesion layer interposed in-between forms a carrier.

4. The method of claim 1, further comprising:
forming a build-up board portion over a surface of the second circuit pattern; and
mounting an active element on a surface of the build-up board portion.

5. The method of claim 1, wherein the dielectric layer further comprises a ceramic filler.

6. The method of claim 5, wherein the ceramic filler comprises any one of barium titanate (BaTiO₃) and strontium titanate (SrTiO₃) or a combination thereof.

7. The method of claim 1, wherein the insulation layer is an organic insulation layer.
